(19) United States
(12) Patent Application Publication
(10) Pub. No.: US 2006/0144819 A1
(43) Pub. Date: Jul. 6, 2006

(54) Remote chamber methods for removing surface deposits

(76) Inventors: Herbert H. Sawin, Chestnut Hill, MA (US); Bo Bai, Cambridge, MA (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/087,787

(22) Filed: Mar. 23, 2005

Related U.S. Application Data
(60) Provisional application No. 60/640,444, filed on Dec. 30, 2004.

(51) Int. Cl. B44C 1/22; H01L 21/302; C23F 1/00; C03C 15/00

(52) U.S. Cl. 216/63; 438/706; 438/905

(57) ABSTRACT

The present invention relates to an improved remote plasma cleaning method for removing surface deposits from a surface, such as the interior of a deposition chamber that is used in fabricating electronic devices. The improvement involves addition of a nitrogen source to the feeding gas mixture comprising of oxygen and fluorocarbon. The improvement also involves pretreatment of interior surface of the pathway from the remote chamber to the surface deposits by activating a pretreatment gas mixture comprising of nitrogen source and passing the activated pretreatment gas through the pathway.

### BACKGROUND OF THE INVENTION

1. Field of the Invention

The present invention relates to methods for removing surface deposits by using an activated gas created by remotely activating a gas mixture comprising of oxygen, fluorocarbon and nitrogen source. More specifically, this invention relates to methods for removing surface deposits from the interior of a chemical vapor deposition chamber by using an activated gas created by remotely activating a gas mixture comprising of oxygen, perfluorocarbon compound and nitrogen source.

2. Description of Related Art

Remote plasma sources for the production of atomic fluorine are widely used for chamber cleaning in the semiconductor processing industry, particularly in the cleaning of chambers used for Chemical Vapor Deposition (CVD) and Plasma Enhanced Chemical Vapor Deposition (PECVD). The use of remote plasma sources avoids some of the erosion of the interior chamber materials that occurs with in situ chamber cleans in which the cleaning is performed by creating a plasma discharge within the PECVD chamber. While capacitively and inductively coupled RF as well as microwave remote sources have been developed for these sorts of applications, the industry is rapidly moving toward transformer coupled inductively coupled sources in which the plasma has a torroidal configuration and acts as the secondary of the transformer. The use of lower frequency RF power allows the use of magnetic cores which enhance the inductive coupling with respect to capacitive coupling; thereby allowing the more efficient transfer of energy to the plasma without excessive ion bombardment which limits the lifetime of the remote plasma source chamber interior.

The semiconductor industry has shifted away from mixtures of fluorocarbons with oxygen for chamber cleaning, which initially were the dominant gases used for in situ chamber cleaning for a number of reasons. First, the emissions of global warming gases from such processes was commonly much higher than that of nitrogen trifluoride (NF₃) processes. NF₃ dissociates more easily in a discharge and is not significantly formed by recombination of the product species. Therefore, low levels of global warming emissions can be achieved more easily. In contrast, fluorocarbons are more difficult to breakdown in a discharge and recombine to form species such as tetrafluoromethane (CF₄) which are even more difficult to break down than other fluorocarbons.

Secondly, it was commonly found that fluorocarbon discharges produced “polymer” depositions that require more frequent wet cleans to remove these deposits that build up after repetitive dry cleans. The propensity of fluorocarbon cleans to deposit “polymers” occurs to a greater extent in remote cleans in which no ion bombardment occurs during the cleaning. These observations dissuaded the industry from developing industrial processes based on fluorocarbon feed gases. In fact, the PECVD equipment manufacturers tested remote cleans based on fluorocarbon discharges, but to date have been unsuccessful because of polymer deposition in the process chambers.

However, if the two drawbacks as described above can be resolved, fluorocarbon gases are desirable for their low cost and low-toxicity.

While prior work has been done on perfluorocarbon/oxygen discharges with nitrogen addition to enhance the etching of silicon nitride. The enhancement is regarded as the result of the formation of NO by the discharge which in turn reacts with N on the silicon nitride surface, followed by the effective fluorination of Si atoms to form volatile products. C. H. Oh et al. Surface and Coatings Technology 171 (2003) 267.

### BRIEF SUMMARY OF THE INVENTION

The present invention relates to a method for removing surface deposits, said method comprising: (a) activating in a remote chamber a gas mixture comprising oxygen, fluorocarbon and a nitrogen source, wherein the molar ratio of oxygen and fluorocarbon is at least 1:3, using sufficient power for a sufficient time such that said gas mixture reaches a neutral temperature of at least about 3,000 K to form an activated gas mixture; and thereafter (b) contacting said activated gas mixture with the surface deposits and thereby removing at least some of said surface deposits.

The present invention also relates to a method for removing surface deposits, said surface deposits is selected from a group consists of silicon, doped silicon, tungsten, silicon dioxide, silicon carbide and various silicon oxygen compounds referred to as low K materials, said method comprising: (a) activating in a remote chamber a gas mixture comprising oxygen, fluorocarbon and a nitrogen source, wherein the molar ratio of oxygen and fluorocarbon is at least 1:3; and thereafter (b) contacting said activated gas mixture with the surface deposits and thereby removing at least some of said surface deposits.

The present invention further relates to a method for removing surface deposits, said method comprising: (a) activating in a remote chamber a pretreatment gas mixture comprising nitrogen source, and thereafter (b) contacting said activated pretreatment gas mixture with at least a portion of interior surface of a pathway from the remote chamber to the surface deposits; (c) activating in the remote chamber a cleaning gas mixture comprising oxygen and fluorocarbon wherein the molar ratio of oxygen and fluorocarbon is at least 1:3; and thereafter (d) passing said activated cleaning gas mixture through said pathway; (e) contacting said activated cleaning gas mixture with the surface deposits and thereby removing at least some of said surface deposits.

### BRIEF DESCRIPTION OF THE DRAWING(S)

FIG. 1. Schematic diagram of an apparatus useful for carrying out the present process.

FIG. 2. Plot of the effect of N₂ addition to 125 sccm Zyron® 8020 on (a) etching rate, (b) power consumption.

FIG. 3. Plot of the effect of N₂ addition to 250 sccm Zyron® 8020 on (a) etching rate, (b) power consumption.

FIG. 4. Plot of the effect of N₂ addition to 250 sccm Zyron® 8020 on the COF₂ emission, measured by FTIR.

FIG. 5. Plot of the effect of N₂ addition to 250 sccm Zyron® 8020 on the various waste gas emission, measured by FTIR.

FIG. 6. Plot of etching rate changes with intermittent N₂ addition.

FIG. 7a. Plot of the effect of N₂ pretreatment on the various waste gas emission, measured by FTIR.

FIG. 7b. Plot of the effect of N₂ pretreatment on the etching rate of Zyron® 8020.

### DETAILED DESCRIPTION OF THE INVENTION

Surface deposits removed in this invention comprise those materials commonly deposited by chemical vapor deposition or plasma-enhanced chemical vapor deposition or similar processes. Such materials include silicon, doped silicon, silicon nitride, tungsten, silicon dioxide, silicon oxynitride, silicon carbide and various silicon oxygen compounds referred to as low K materials, such as FSG (fluorosilicate glass) and SiCOH or PECVD OSG including Black Diamond (Applied Materials), Coral (Novellus Systems) and Aurora (ASM International).

One embodiment of this invention is removing surface deposits from the interior of a process chamber that is used in fabricating electronic devices. Such process chamber could be a Chemical Vapor Deposition (CVD) chamber or a Plasma Enhanced Chemical Vapor Deposition (PECVD) chamber.

The process of the present invention involves an activating step using sufficient power to form an activated gas mixture. Activation may be accomplished by any means allowing for the achievement of dissociation of a large fraction of the feed gas, such as: RF energy, DC energy, laser illumination and microwave energy. The neutral temperature of the resulting plasma depends on the power and the residence time of the gas mixture in the remote chamber. In this invention, it is found that addition of nitrogen gas helps absorption of RF power. Under certain power input and conditions, neutral temperature will be higher with longer residence time. Here, preferred neutral temperature is over about 3,000 K. Under appropriate conditions (considering power, gas composition, gas pressure and gas residence time), neutral temperatures of at least about 6000 K may be achieved, for example, with octafluorocyclobutane.

The activated gas is formed in a remote chamber that is outside of the process chamber, but in close proximity to the process chamber. The remote chamber is connected to the process chamber by any means allowing for transfer of the activated gas from the remote chamber to the process chamber. The remote chamber and means for connecting the remote chamber with the process chamber are constructed of materials known in this field to be capable of containing activated gas mixtures. For instance, aluminum and stainless steel are commonly used for the chamber components. Sometimes Al₂O₃ is coated on the interior surface to reduce the surface recombination.

The gas mixture that is activated to form the activated gas comprises oxygen, nitrogen source and fluorocarbon. A fluorocarbon of the invention is herein referred to as a compound comprising of C and F. Preferred fluorocarbon in this invention is perfluorocarbon compound. A perfluorocarbon compound in this invention is herein referred to as a compound consisting of C, F and optionally oxygen. Such perfluorocarbon compounds include, but are not limited to tetrafluoromethane, hexafluoroethane, octafluoropropane, hexafluorocyclopropane decafluorobutane, octafluorocyclobutane, carbonyl fluoride and octafluorotetrahydrofuran. A preferred gas mixture has oxygen to fluorocarbon molar ratio of at least 1:3. A more preferred gas mixture has oxygen to fluorocarbon molar ratio of at least from about 2:1 to about 20:1

A “nitrogen source” of the invention is herein referred to as a gas which can generate atomic nitrogen under the discharge conditions in this invention. Examples of a nitrogen source here include, but are not limited to N₂, NF₃ and all kinds of nitrogen oxides such as NO, N₂O, NO₂ et al.

The gas mixture that is activated to form the activated gas may further comprise carrier gases such as argon and helium.

A preferred embodiment of the present invention is a method for removing surface deposits from the interior of a process chamber that is used in fabricating electronic devices, said method comprising: (a) activating in a remote chamber a gas mixture comprising oxygen, perfluorocarbon compound and a nitrogen source, wherein the molar ratio of oxygen and perfluorocarbon compound is at least 1:3, using sufficient power for a sufficient time such that said gas mixture reaches a neutral temperature of at least about 3,000 K to form an activated gas mixture; and thereafter (b) contacting said activated gas mixture with the interior of said deposition chamber and thereby removing at least some of said surface deposits.

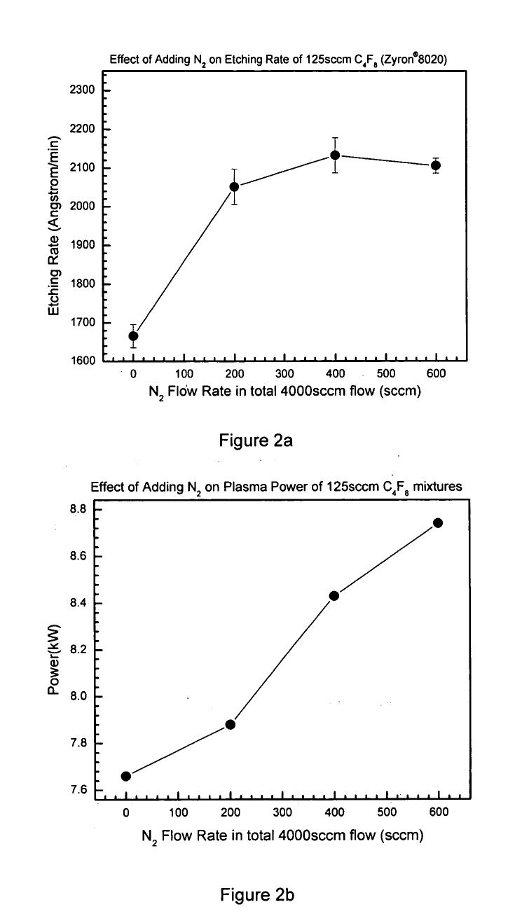

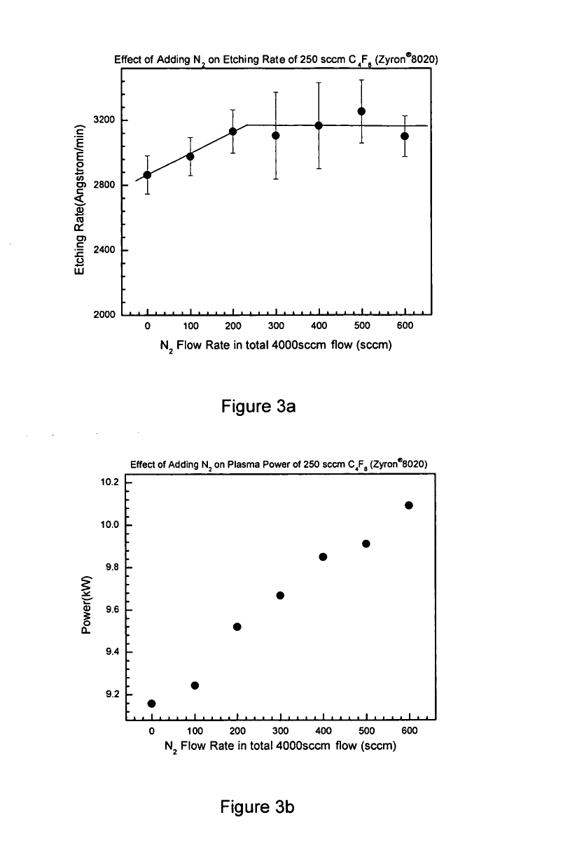

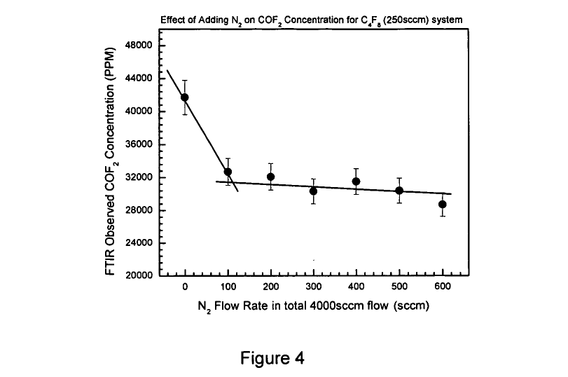

It was found in this invention that nitrogen gas can dramatically increase the etching rate. In one embodiment of this invention, the perfluorocarbon compound is octafluorocyclobutane (Zyron® 8020) manufactured by DuPont. As demonstrated in the examples shown below, without nitrogen gas, Zyron® 8020 generated low etching rate and high COF₂ emission. The etching rate starts to improve with a small amount of nitrogen and saturates when nitrogen addition exceeds certain amount. (see FIGS. 2 and 3) The nitrogen addition also increases the power consumption and decreases the COF₂ emission. (see FIGS. 2 and 4)

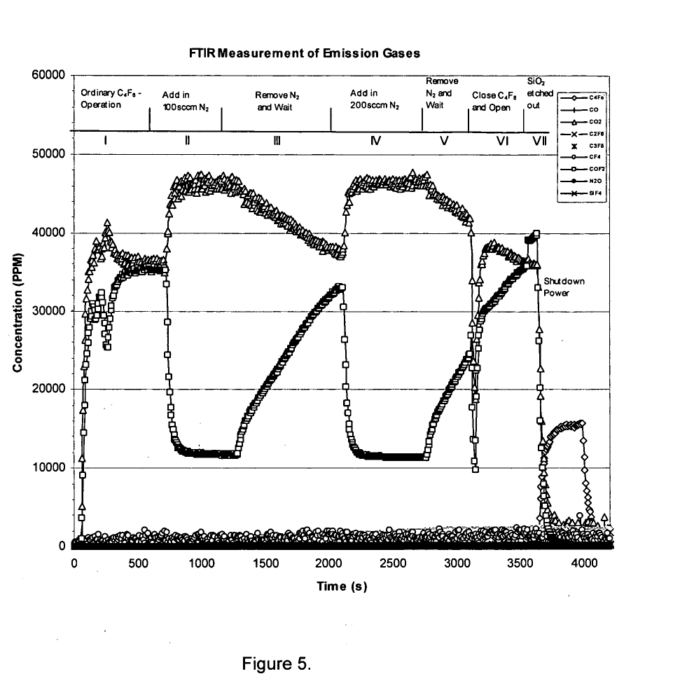

It was also found that at the similar conditions of this invention, the drawbacks of the perfluorocarbon compound, i.e. global warming gases emission and polymer deposition, can be overcome. In the experiments of this invention, no significant polymer depositions on the interior surface of chamber was found. The global warming gas emissions were also very low as shown in FIG. 5.

It was further found that some pretreatment of interior surface of the pathway from the remote chamber to the surface deposits can increase the etching rate. In this invention, the pretreatment is achieved by activating a pretreatment gas mixture comprising of nitrogen source and passing the activated pretreatment gas through the pathway. In one embodiment as described in Example 4, the pathway from the remote chamber to the surface deposits was pretreated for 3 seconds by an activated nitrogen and argon gas mixture. After the pretreatment, the etching rate started at a high level.

Alternatively, the system can be used to alter surfaces placed in the remote chamber by contact with the fluorine atoms and other constituents coming from the source.

The following Examples are meant to illustrate the invention and are not meant to be limiting.

### EXAMPLES

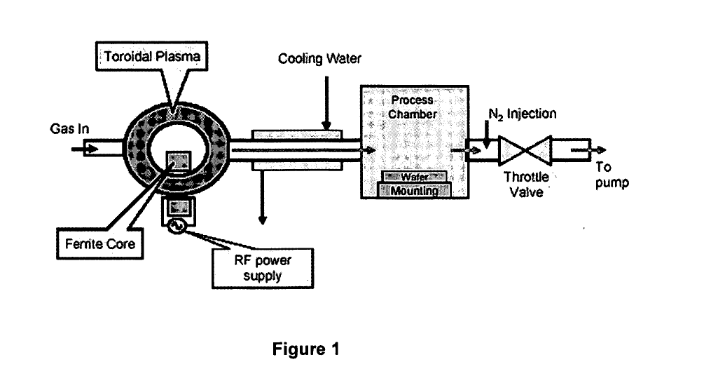

FIG. 1 shows a schematic diagram of the remote plasma source and apparatus used to measure the etching rates, plasma neutral temperatures, and exhaust emissions. The remote plasma source is a commercial toroidal-type MKS ASTRON®ex reactive gas generator unit made by MKS Instruments, Andover, Mass., USA. The feed gases (e.g. oxygen, fluorocarbon, nitrogen source, Argon) were introduced into the remote plasma source from the left, and passed through the toroidal discharge where they were discharged by the 400 KHz radio-frequency power to form an activated gas mixture. The oxygen is manufactured by Airgas with 99.999% purity. The fluorocarbon is Zyron® 8020 manufactured by DuPont with minimum 99.9 vol % of octafluorocyclobutane. Nitrogen source in the examples is nitrogen gas manufactured by Airgas with grade of 4.8 and Argon is manufactured by Airgas with grade of 5.0. The activated gas then passed through an aluminum water-cooled heat exchanger to reduce the thermal loading of the aluminum process chamber. The surface deposits covered wafer was placed on a temperature controlled mounting in the process chamber. The neutral temperature is measured by Optical Emission Spectroscopy (OES), in which rovibrational transition bands of diatomic species like C₂ and N₂ are theoretically fitted to yield neutral temperature. See also B. Bai and H. Sawin, Journal of Vacuum Science & Technology A 22 (5), 2014 (2004), herein incorporated as a reference. The etching rate of the surface deposits by the activated gas is measured by interferometry equipment in the process chamber. N₂ gas is added at the entrance of the pump both to dilute the products to a proper concentration for FTIR measurement and to reduce the hang-up of products in the pump. FTIR was used to measure the concentration of species in the pump exhaust.

### Example 1

The feeding gas composed of O₂, Zyron® 8020 (C₄F₈), Ar, N₂, wherein O₂ flow rate is 1542 sccm, Ar flow rate is 2333 sccm, C₄F₈ flow rate is 125 sccm, N₂ flow rate is 0, 200, 400, 600 sccm respectively. Chamber pressure is 2 torr. The feeding gas was activated by 400 KHz RF power to a neutral temperature of more than 5000 K. The activated gas then entered the process chamber and etched the SiO₂ surface deposits on the mounting with the temperature controlled at 200° C. The results are showed in FIG. 2.

### Example 2

The feeding gas composed of O₂, Zyron® 8020 (C₄F₈), Ar, N₂, wherein O₂ flow rate is 1750 sccm, Ar flow rate is 2000 sccm, C₄F₈ flow rate is 250 sccm, N₂ flow rate is 0, 100, 200, 300, 400, 500, 600 sccm respectively. Chamber pressure is 2 torr. The feeding gas was activated by 400 KHz RF power to a neutral temperature of 5500 K. The activated gas then entered the process chamber and etched the SiO₂ surface deposits on the mounting with the temperature controlled at 200° C. The results are showed in FIG. 3. In this experiment, the COF₂ concentration in the pump exhaust was monitored by FTIR and shown in FIG. 4.

### Example 3

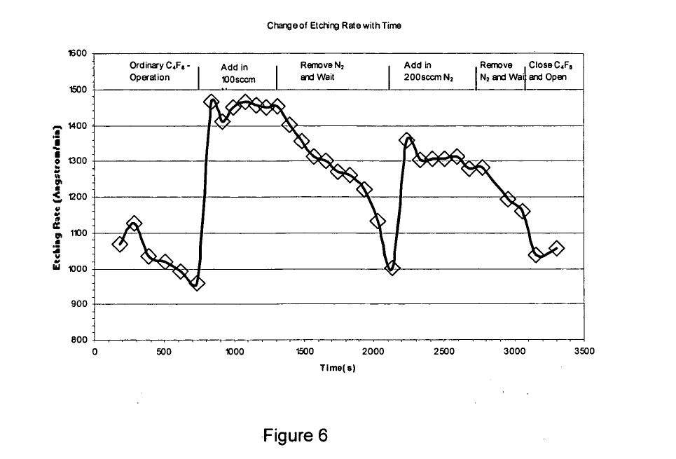

The initial feeding gas composed of O₂, Zyron® 8020 (C₄F₈), Ar, wherein O₂ flow rate is 1750 sccm, Ar flow rate is 2000 sccm, C₄F₈ flow rate is 250 sccm. The process chamber pressure is 2 torr. The mounting with SiO₂ surface deposits on it was controlled at 100° C. The emission gases of C₄F₈, CO, CO₂, C₂F₆, C₃F₈, CF₄, COF₂, N₂O, NF₃ and SiF₄ were monitored by FTIR and shown in FIG. 5. The plasma was ignited at the time of 250 seconds by 400 KHz RF power and the neutral temperature rose to about 5500 K. There were no N₂ addition at the beginning and the etching rate was low (see FIG. 6), the COF₂ emission was high and the CO₂ emission was low. At the 720 seconds, 100 sccm N₂ was added to the feeding gas. As a result, etching rate jumped up, COF₂ emission dropped and the CO₂ emission increased immediately. At the 1280 seconds, N2 flow was stopped. The etching rate, COF₂ emission and CO₂ emission all slowly recovered to the previous level. 200 sccm of N₂ flow was added starting at the 2100 seconds and was stopped at the 2780 seconds. The same type of changes repeated. At the 3100 seconds, the C₄F₈ flow was stopped for 5 seconds. After a dip of etching rate, COF₂ and CO₂ emission, the system recovered and continued the transition. The power was turned off at the 3600 seconds. From FIG. 5, it may be expected that the addition of 200 sccm of N₂ would increase the etching rate to the same level as the addition of 100 sccm of N₂ did. However, it was observed that the etching rate slightly decreased after the first two micrometer of the surface deposits were etched away, probably due to the change of the roughness of the film.

### Example 4

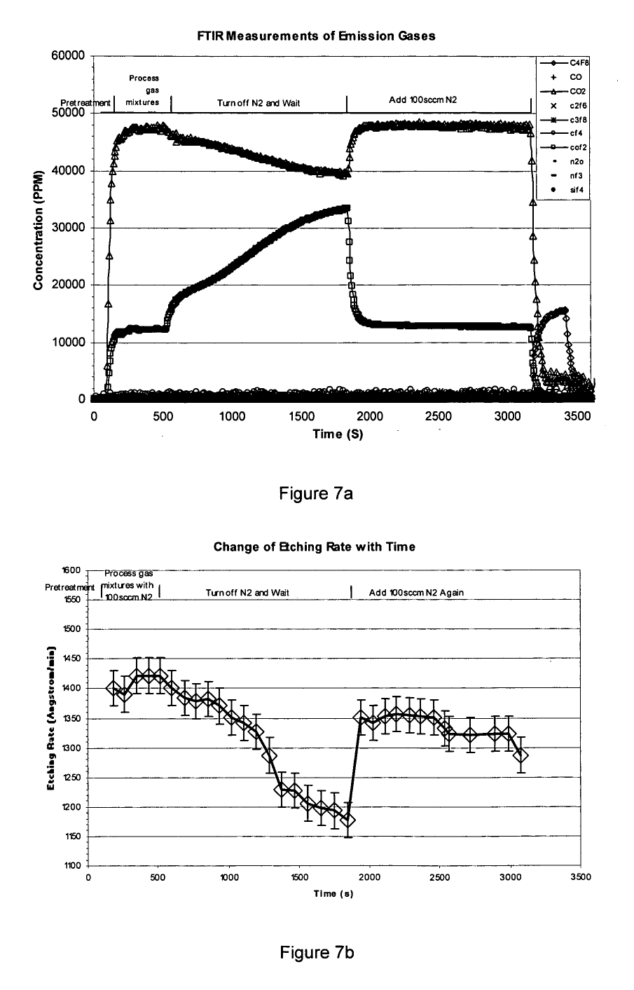

The pretreatment gas mixture was composed of 100 sccm of N₂ and 2000 sccm of Ar. It was activated by 400 KHz RF power and the neutral temperature was about 2000 K. Starting at the 100 seconds and continuing for 3 seconds, the activated gas passed through from the remote chamber to the process chamber with the SiO₂ surface deposits on the mounting with the temperature controlled at 100° C. Then the gas mixture composing of 1750 sccm O₂ and 250 sccm Zyron® 8020 (C₄F₈) were added in. The cleaning gas mixture was activated by 400 KHz RF power and the neutral temperature was about 5500 K. The process chamber pressure was 2 torr. The mounting with SiO₂ surface deposits on it was controlled at 100° C. The emission gases of C₄F₈, CO, CO₂, C₂F₆, C₃F₈, CF₄, COF₂, N₂O, NF₃ and SiF₄ were monitored by FTIR and shown in FIG. 7a. After the pretreatment, the etching rate started at a high level, as shown in FIG. 7b, and the COF₂ emission was low. With cleaning gas mixture containing N₂, the system was kept in a high etching rate state. At the time of about 500 seconds, N₂ was removed from the cleaning gas mixture, causing the etching rate to drop slowly and the COF₂ emission to increase slowly. At the time of 1850 seconds, 100 sccm N₂ was added back to the cleaning gas mixture. As a result, etching rate jumped up, COF₂ emission dropped and the CO₂ emission increased immediately. The power was turned off at the 3160 seconds.

What is claimed is:

1. A method for removing surface deposits, said method comprising:
(a) activating in a remote chamber a gas mixture comprising oxygen, fluorocarbon and a nitrogen source, wherein the molar ratio of oxygen and fluorocarbon is at least 1:3, using sufficient power for a sufficient time such that said gas mixture reaches a neutral temperature of at least about 3,000 K to form an activated gas mixture; and thereafter
(b) contacting said activated gas mixture with the surface deposits and thereby removing at least some of said surface deposits.

2. The method of claim 1 wherein said surface deposits is removed from the interior of a deposition chamber that is used in fabricating electronic devices.

3. The method of claim 1 wherein said power is generated by an RF source, a DC source or a microwave source.

4. The method of claim 1 wherein said nitrogen source is nitrogen gas, NF₃, or nitrogen oxides.

5. The method of claim 1 wherein said fluorocarbon is a perfluorocarbon compound.

6. The method of claim 5 wherein said perfluorocarbon compound is selected from the group consisting of tetrafluoromethane, hexafluoroethane, octafluoropropane, octafluorocyclobutane, carbonyl fluoride, perfluorotetrahydrofuran.

7. The method of claim 1 wherein said gas mixture further comprises a carrier gas.

8. The method of claim 7 wherein said carrier gas is at least one gas selected from the group of gases consisting of argon and helium.

9. The method of claim 1, wherein the pressure in the remote chamber is between 0.01 Torr and 20 Torr.

10. The method of claim 1, wherein the surface deposit is selected from a group consisting of silicon, doped silicon, silicon nitride, tungsten, silicon dioxide, silicon oxynitride, silicon carbide and various silicon oxygen compounds referred to as low K materials.

11. The method of claim 1, wherein the molar ratio of oxygen and fluorocarbon is at least from about 2:1 to about 20:1.

12. A method for removing surface deposits, said surface deposits is selected from a group consists of silicon, doped silicon, tungsten, silicon dioxide, silicon carbide and various silicon oxygen compounds referred to as low K materials, said method comprising:
(a) activating in a remote chamber a gas mixture comprising oxygen, fluorocarbon and a nitrogen source, wherein the molar ratio of oxygen and fluorocarbon is at least 1:3; and thereafter
(b) contacting said activated gas mixture with the surface deposits and thereby removing at least some of said surface deposits.

13. The method of claim 12 wherein said surface deposits is removed from the interior of a deposition chamber that is used in fabricating electronic devices.

14. The method of claim 12 wherein said nitrogen source is nitrogen gas, NF₃, or nitrogen oxides.

15. The method of claim 12 wherein said fluorocarbon is a perfluorocarbon compound.

16. A method for removing surface deposits, said method comprising:
(a) activating in a remote chamber a pretreatment gas mixture comprising nitrogen source, and thereafter
(b) contacting said activated pretreatment gas mixture with at least a portion of interior surface of a pathway from the remote chamber to the surface deposits;
(c) activating in the remote chamber a cleaning gas mixture comprising oxygen and fluorocarbon wherein the molar ratio of oxygen and fluorocarbon is at least 1:3; and thereafter
(d) passing said activated cleaning gas mixture through said pathway;
(e) contacting said activated cleaning gas mixture with the surface deposits and thereby removing at least some of said surface deposits.
